(19) United States
(12) Patent Application Publication
(10) Pub. No.: US 2026/0324357 A1
(43) Pub. Date: Oct. 15, 2026

(54) CERAMIC SUSCEPTOR

(71) Applicant: NGK Corporation, Nagoya-shi (JP)

(72) Inventor: Tomohiro HARA, Handa-shi (JP)

(21) Appl. No.: 19/690,320

(22) Filed: May 28, 2026

Related U.S. Application Data
(63) Continuation of application No. PCT/JP2024/001032, filed on Jan. 16, 2024.

(51) Int. Cl. H10P 72/72; H01J 37/32

(52) U.S. Cl. CPC H10P 72/722; H01J 37/32715; H01J 2237/2007; H01J 2237/20235; H01J 2237/3323

(57) ABSTRACT

Provided is a ceramic susceptor including a ceramic plate having a first surface with a plurality of projections, and a second surface, a first RF electrode made of metal mesh and embedded in the ceramic plate at a depth of a distance L₁ from top surfaces of the projections, a second RF electrode made of metal mesh and embedded in the ceramic plate at a depth of a distance L₂ (where L₂>L₁) from the top surfaces of the projections, and lift pin holes each having a sectional area S_{L} that penetrate the ceramic plate. The first RF electrode has opening holes each having an area S₁ in positions corresponding to the lift pin holes. The second RF electrode has opening holes each having an area S₂ in positions corresponding to the lift pin holes. The sectional area S_{L}, the area S₁, and the area S₂ satisfy 3.0≤S₁/S_{L}≤10.5 and 2.0≤S₂/S_{L}≤4.5.

### CROSS-REFERENCE TO RELATED APPLICATION

This application is a continuation application of PCT/JP2024/001032 filed Jan. 16, 2024, the entire contents of which are incorporated herein by reference.

### BACKGROUND OF THE INVENTION

### 1. Field of the Invention

The present disclosure relates to a ceramic susceptor.

### 2. Description of the Related Art

In film deposition apparatuses and etching apparatuses for semiconductor manufacturing processes, susceptors are used to support wafers. Among such susceptors, a susceptor is widely used that includes a ceramic plate for a wafer to be placed, and a cylindrical ceramic shaft that is attached to this ceramic plate. A ceramic plate generally has a structure in which internal electrodes such as a heater electrode, RF electrodes, and an electrostatic chuck (ESC) electrode are embedded inside a ceramic substrate made of aluminum nitride (AlN) or the like, which has excellent heat resistance and corrosion resistance.

There is known a ceramic susceptor that includes lift pin holes in a plate portion of the susceptor on which a wafer is to be placed. The lift pin holes are holes that are used for inserting lift pins for lifting the wafer after being subjected to a process such as a film depositing process, from below, and a plurality (for example, three or four) of lift pin holes are generally provided at positions that are spaced apart from one another.

Patent Literature 1 (JP2005-340442A) discloses an electrostatic chuck that includes an absorption electrode that is provided on one main surface of a platy body, and an insulation layer provided on the absorption electrode. An upper surface of this insulation layer serves as a mounting surface for placing a wafer. The absorption electrode is bent in a peripheral portion of the absorption electrode to a side opposite to the wafer mounting surface, and a chamfered portion is formed at the insulation layer that covers the peripheral portion of the absorption electrode. The electrostatic chuck disclosed in this literature includes the lift pin holes, and the peripheral portion of the absorption electrode is disclosed to include the lift pin holes.

### CITATION LIST

### Patent Literature

Patent Literature 1: JP2005-340442A

### SUMMARY OF THE INVENTION

As described above, the lift pins have a function of lifting up the wafer placed on the ceramic susceptor. Therefore, the plate portion (ceramic plate) of the ceramic susceptor requires through-holes for inserting the lift pins, that is, the lift pin holes. Accordingly, as for the RF electrode (for example, a mesh-shaped electrode) that is embedded in the ceramic plate, it is necessary to provide opening holes at positions corresponding to the lift pin holes. However, since the RF electrodes are electrodes for plasma generation, the density of plasma decreases around the lift pin holes, which easily creates singularities in the film deposition distribution. With such singularities, the film deposited by using the ceramic susceptor has large variations in film thickness, as a result of which, the yield of semiconductor chips may decrease.

The present inventors have now found that, by embedding a first RF electrode and a second RF electrode in positions at depths that are different from each other of the ceramic plate, and by causing a sectional area S_{L} of lift pin holes, an area S₁ of opening holes in positions corresponding to the lift pin holes, of the first RF electrode, and an area S₂ of opening holes in positions corresponding to the lift pin holes, of the second RF electrode to satisfy predetermined relationships, it is possible to suppress a decrease in plasma density around the lift pin holes and to achieve film deposition with excellent uniformity of film thickness.

Accordingly, an object of the present invention is to provide a ceramic susceptor that, while having lift pin holes, is capable of suppressing a decrease in plasma density around the lift pin holes and achieving film deposition with excellent uniformity of film thickness.

The present disclosure provides the following aspects.

### [Aspect 1]

A ceramic susceptor, comprising:
a ceramic plate in a disk shape having a first surface provided with a plurality of projections having a constant height, and a second surface opposing the first surface;
a first RF electrode that is made of metal mesh having a circular shape with a diameter d₁, and is embedded in a position at a depth of a distance L₁ from top surfaces of the projections in the ceramic plate;
a second RF electrode that is made of metal mesh having a circular shape with a diameter d₂, and is embedded in a position at a depth of a distance L₂ (where L₂>L₁) from the top surfaces of the projections in the ceramic plate; and
a plurality of lift pin holes each having a sectional area S_{L} that penetrate to the second surface from the first surface of the ceramic plate,
wherein the first RF electrode has opening holes each having an area S₁ in a plurality of positions corresponding to the lift pin holes, and the second RF electrode has opening holes each having an area S₂ in a plurality of positions corresponding to the lift pin holes,
wherein the sectional area S_{L}, the area S₁, and the area S₂ satisfy relationships below:

3.0≤S₁/S_{L}≤10.5, and

2.0≤S₂/S_{L}≤4.5.

### [Aspect 2]

The ceramic susceptor according to aspect 1, wherein when expressed in units of millimeters, the distance L₁ and the distance L₂ satisfy relationships below:

0.9≤L₁51.5, and

2.0≤L₂≤3.0.

### [Aspect 3]

The ceramic susceptor according to aspect 1 or 2, wherein when expressed in units of millimeters, the diameter d₁ and the diameter d₂ satisfy relationships below:

290≤d₁≤300, and

310≤d₂≤350.

### [Aspect 4]

The ceramic susceptor according to any one of aspects 1 to 3, wherein the ceramic plate has a diameter of from 330 to 380 mm.

### [Aspect 5]

The ceramic susceptor according to any one of aspects 1 to 4, wherein the ceramic plate contains aluminum nitride and/or aluminum oxide.

### [Aspect 6]

The ceramic susceptor according to any one of aspects 1 to 5, further comprising a ceramic shaft in a cylindrical shape that is attached to the second surface of the ceramic plate, and includes an internal space.

### [Aspect 7]

The ceramic susceptor according to aspect 6, further comprising RF rods that are connected to the first RF electrode and the second RF electrode respectively, and extend through the internal space.

### [Aspect 8]

The ceramic susceptor according to any one of aspects 1 to 7, wherein the lift pin holes have a circular shape in plan view.

### [Aspect 9]

The ceramic susceptor according to any one of aspects 1 to 8, wherein the number of the lift pin holes is three or four.

### [Aspect 10]

The ceramic susceptor according to any one of aspects 1 to 9, wherein each of the lift pin holes has a diameter of 1 to 5 mm.

### [Aspect 11]

The ceramic susceptor according to any one of aspects 1 to 10, wherein the first RF electrode and/or the second RF electrode also has a function of an ESC electrode.

### [Aspect 12]

The ceramic susceptor according to any one of aspects 1 to 11, further comprising a heater electrode that is embedded in a position at a depth closer to the second surface than the first RF electrode and the second RF electrode in the ceramic plate.

### [Aspect 13]

The ceramic susceptor according to aspect 12, further comprising:
a ceramic shaft in a cylindrical shape that is attached to the second surface of the ceramic plate, and includes an internal space; and
a heater rod that is connected to the heater electrode, and extends through the internal space.

### BRIEF DESCRIPTION OF THE DRAWINGS

FIG. 1 is a schematic sectional view showing an example of a ceramic susceptor according to the present invention.

FIG. 2 is a schematic top view showing an example of the ceramic susceptor shown in FIG. 1.

FIG. 3 is a schematic top view showing a first RF electrode shown in FIG. 1.

FIG. 4 is a schematic top view showing a second RF electrode shown in FIG. 1.

### DETAILED DESCRIPTION OF THE INVENTION

A ceramic susceptor according to the present invention is a base made of ceramics for supporting a wafer in a semiconductor manufacturing apparatus. Preferably, the ceramic susceptor according to the present invention is a ceramic heater for a semiconductor film deposition apparatus. Typical examples of the film deposition apparatus include CVD (Chemical Vapor Deposition) apparatuses (for example, a thermal CVD apparatus, a plasma CVD apparatus, an optical CVD apparatus, and an MOCVD apparatus) and a PVD (Physical Vapor Deposition) apparatus, and a plasma CVD apparatus is particularly preferable.

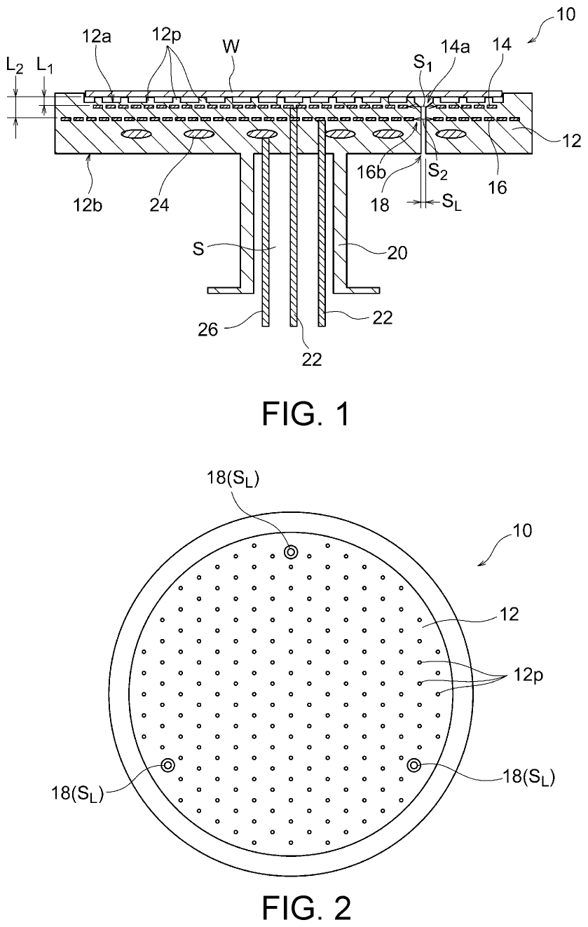

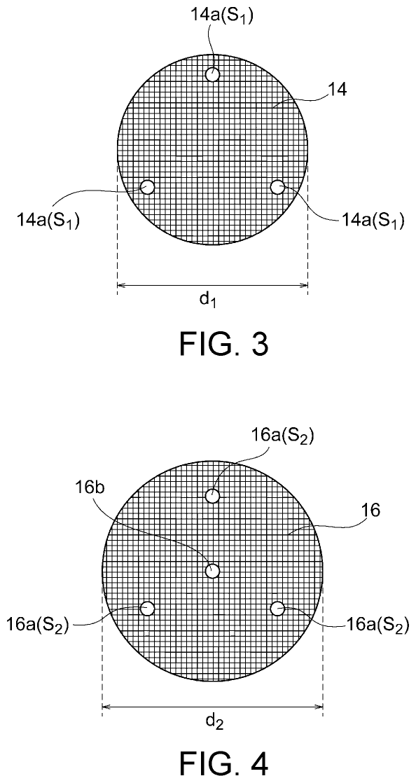

FIGS. 1 and 2 show an example of the ceramic susceptor. A ceramic susceptor 10 shown in FIGS. 1 and 2 includes a ceramic plate 12, a first RF electrode 14, a second RF electrode 16, a lift pin hole 18, and optionally, a ceramic shaft 20. The ceramic plate 12 has a disk shape and has a first surface 12a provided with a plurality of projections 12p having a constant height, and a second surface 12b opposing the first surface 12a. The first surface 12a is a surface for a wafer W to be placed, and more specifically, the wafer W can be placed on top surfaces of the projections 12p that partially compose the first surface 12a. The first RF electrode 14 is made of a metal mesh having a circular shape with a diameter d₁, and is embedded in a position at a depth of a distance L₁ from a top surface of the projection 12p in the ceramic plate 12. The second RF electrode 16 is made of a metal mesh having a circular shape with a diameter d₂, and is embedded in a position at a depth of a distance L₂ (where L₂>L₁) from the top surface of the projection 12p in the ceramic plate 12. The lift pin holes 18 are a plurality of holes that penetrate to the second surface 12b from the first surface 12a of the ceramic plate 12, and a sectional area of each of the lift pin holes 18 is referred to as S_{L}. As shown in FIG. 3, the first RF electrode 14 has opening holes 14a at a plurality of positions corresponding to the lift pin holes 18, and an area of each of the opening holes 14a is referred to as S₁. As shown in FIG. 4, the second RF electrode 16 has opening holes 16a at a plurality of positions corresponding to the lift pin holes 18, and an area of each of the opening holes 16a is referred to as S₂. The sectional area S_{L}, the area S₁ and the area S₂ satisfy relationships of 3.0≤S₁/S_{L}≤10.5, and 2.0≤S₂/S_{L}≤4.5. In this manner, by embedding the first RF electrode 14 and the second RF electrode 16 in the positions at the depths that are different from each other in the ceramic plate 12, and causing the sectional area S_{L} of the lift pin hole 18, the area S₁ of the opening hole at the position corresponding to the lift pin hole 18 of the first RF electrode 14, and the area S₂ of the opening hole at the position corresponding to the lift pin hole of the second RF electrode to satisfy the predetermined relationships, it is possible to suppress a decrease of the plasma density around the lift pin holes 18 and to achieve film deposition with excellent uniformity of film thickness.

That is to say, as described above, when providing the lift pin holes in the ceramic plate, it is also necessary to provide the opening holes at the positions corresponding to the lift pin holes in the RF electrodes that are embedded in the ceramic plate. However, since the RF electrodes are electrodes for plasma generation, the density of plasma decreases around the lift pin holes, which easily become singularities of the film deposition distribution. With such singularities, the film that is deposited by using the ceramic susceptor has large variations in film thickness, as a result of which, the yield of semiconductor chips may decrease. Such a problem is successfully solved according to the present invention. That is to say, two types of RF electrodes that are the first RF electrode 14 and the second RF electrode 16 are embedded in the positions at the depths different from each other, and the areas (namely, S₁ and S₂) of the opening holes 14a and 16a of the first RF electrode 14 and the second RF electrode 16 are controlled in relation to the sectional area S_{L} of the lift pin hole 18 to satisfy the aforementioned relationships. In doing so, it is possible to suppress decrease in plasma density (that would occur if the second RF electrode 16 is absent) around the opening holes 14a of the first RF electrode 14. That is to say, while desired plasma is being generated by the first RF electrode 14, a decrease in plasma density due to the opening hole 14a can be compensated for by plasma generated at the second RF electrode 16. The second RF electrode 16 also has the opening hole 16a, but it is conceivable that the complementary effect of the second RF electrode 16 on plasma density outweighs the decrease in plasma density due to the opening hole 16a by satisfying the relationships of 3.0≤S₁/S_{L}≤10.5, and 2.0≤S₂/S_{L}4.5. In other words, it can be said that the presence of the second RF electrode 16 decreases an influence of the lift pin holes 18 and the opening holes 14a of the first RF electrode 14 as the singularities. As a result, it is possible to suppress decrease in plasma density around the lift pin holes 18 to achieve film deposition with excellent uniformity of film thickness.

From this perspective, the sectional area S_{L} and the area S₁ satisfy 3.0≤S₁/S_{L}≤10.5, preferably satisfy 4.0≤S₁/S_{L}≤10.0, more preferably satisfy 4.0≤S₁/S_{L}≤8.0, and particularly preferably satisfy a relationship of 4.0≤S₁/S_{L}≤6.0. Furthermore, the sectional area S_{L} and the area S₂ satisfy 2.0≤S₂/S_{L}≤4.5, preferably satisfy 2.5≤S₂/S_{L}≤4.5, and more preferably satisfy a relationship of 3.0≤S₂/S_{L}≤4.0. Note that a diameter of the lift pin hole 18 may not be constant in the depth direction. For example, as shown in FIG. 1, the lift pin hole 18 may be enlarged in diameter in a vicinity of the first surface 12a. In such a case, the sectional area S_{L} of the lift pin hole 18 is defined as a sectional area of the hole observed as the through-hole when the ceramic plate 12 is seen in a plan view. Accordingly, in an aspect shown in FIG. 1, the sectional area of the lift pin hole 18 when seen from the second surface 12b can be adopted as the sectional area S_{L} of the lift pin hole 18.

The ceramic plate 12 is not particularly limited as long as it has a disk shape including a plurality of protrusions 12p of a constant height on the first surface 12a, and can have a similar configuration to ceramic plates that are adopted in known ceramic susceptors. From the perspective of excellent thermal conductivity, high electrical insulation, thermal expansion similar to silicon, and the like, in the ceramic plate 12, a main part (that is, the ceramic substrate), other than embedded members such as the first RF electrode 14, the second RF electrode 16, and a heater electrode 24, preferably contains aluminum nitride or aluminum oxide, and more preferably contains aluminum nitride.

The ceramic plate 12 has a disk shape. However, the shape of the disk-shaped ceramic plate 12 in plan view does not need to be a perfect circle, and for example, it may be an incomplete circle with a portion missing, like an orientation flat. A size of the ceramic plate 12 is not particularly limited and can be appropriately determined according to the diameter of the wafer that is intended to be used, but it is typically from 330 to 380 mm. Furthermore, the thickness of the ceramic plate 12 is typically from 10 to 25 mm.

The first surface 12a of the ceramic plate 12 includes a plurality of protrusions 12p of a constant height. The protrusions 12p are for contacting the back surface of the wafer W and supporting the wafer W, and are preferably formed at equal intervals from one another on the first surface 12a of the ceramic plate 12. A shape of each of the protrusions 12p is not particularly limited, but it is preferably cylindrical. A diameter of each of the protrusions 12p is not particularly limited, but it is preferably from 0.1 to 8 mm, more preferably from 0.5 to 5 mm, still more preferably from 0.5 to 4 mm, and particularly preferably from 0.70 to 2.54 mm. The protrusions 12p are preferably formed integrally with the ceramic plate 12 by embossing or the like. Accordingly, the protrusions 12p also preferably contain aluminum nitride or aluminum oxide, and more preferably contain aluminum nitride, similarly to the ceramic plate 12. A height of the protrusion 12p is not particularly limited, but it is preferably from 0.001 to 0.1 mm, more preferably from 0.005 to 0.08 mm, still more preferably from 0.01 to 0.05 mm, and particularly preferably 0.01 to 0.03 mm. A distance between central axes of the adjacent protrusions 12p is preferably from 4 to 30 mm, more preferably from 5 to 26 mm, still more preferably from 7 to 26 mm, and particularly preferably from 7 to 15 mm.

A plurality of projections 12p are preferably positioned according to a regular pattern in which one selected from the group consisting of a circle, a square, an equilateral triangle, and a regular hexagon is used as a constituent unit (or in such a manner as to form such a regular pattern). That is to say, it is preferable that the centers of the plurality of projections 12p are positioned to be located on imaginary lines (for example, at vertices in the case of a polygon) that constitute the regular pattern in which a plurality of the above-described constituent units are repeated. In other words, it is preferable that an imaginary figure drawn connecting the centers of the adjacent protrusions 12p form the regular pattern in which one selected from the group consisting of a circle, a square, an equilateral triangle, and a regular hexagon is the constituent unit.

The first RF electrode 14 and the second RF electrode 16 are electrodes that are subjected to high-frequency power to thereby enable film deposition by a plasma CVD process. The first RF electrode 14 and the second RF electrode 16 are each made of metal mesh similarly to known RF electrodes. The metal mesh can be, for example, made by weaving thin metal wires together in a mesh shape to be formed into a sheet shape.

The first RF electrode 14 and the second RF electrode 16 are respectively embedded in the positions at the depths of distances L₁ and L₂ from the top surface of the projection 12p in the ceramic plate 12 (where L₂>L₁). That is to say, the first RF electrode 14 is embedded in the position at the depth relatively close to the first surface 12a, while the second RF electrode 16 is embedded in the position at the depth further away from the first surface 12a than the first RF electrode 14. When the distance L₁ is expressed in units of millimeters, it preferably satisfies 0.9≤L₁≤1.5, more preferably satisfies 1.0≤L₁≤1.5, and still more preferably satisfies 1.0≤L₁≤1.3, while when the distance L₂ is expressed in units of millimeters, it preferably satisfies 2.0≤L₂≤3.0, and more preferably satisfies 2.5≤L₂≤2.8. By keeping the distances within these ranges, plasma can be generated in a well-balanced manner by the first RF electrode 14 and the second RF electrode 16. That is to say, by maintaining the distance L₁ that is not too small, it is possible to prevent the influence of the first RF electrode 14 on the plasma from being excessively large. Furthermore, since the distance of the distance L₂ is not excessively large, the ceramic portion that functions as a dielectric layer and positioned on the top surface of the second RF electrode 16 does not become too thick, and therefore, it is possible to reliably bring about the influence of the second RF electrode 16 on the plasma (in particular, the effect of compensating the plasma density).

The first RF electrode 14 and the second RF electrode 16 respectively have circular shapes with diameters d₁ and d₂. The circular shapes of the first RF electrode 14 and the second RF electrode 16 do not need to be perfect circles, and, for example, they may be incomplete circles with portions missing, like an orientation flat (orientation flat), similarly to the ceramic plate 12. The first RF electrode 14 and the second RF electrode 16 preferably have sizes slightly smaller in diameter than the ceramic plate 12, and may have different sizes from each other. In this regard, it is preferable that the diameter d₂ of the second RF electrode 16 is larger than the diameter d₁ of the first RF electrode 14, because this can more increase the plasma density in the outer peripheral portion of the ceramic plate 12. Specifically, when expressed in units of millimeters, the diameter d₁ and the diameter d₂ are preferably satisfy 290≤d₁≤300 and 310≤d₂≤350, and more preferably satisfy 295≤d₁≤300 and 315≤d₂≤330.

As shown in FIG. 3, the first RF electrode 14 has the opening holes 14a at the plurality of positions corresponding to the lift pin holes 18. Furthermore, as shown in FIG. 4, the second RF electrode 16 has the opening holes 16a at the plurality of positions corresponding to the lift pin holes 18. The second RF electrode 16 can also have another opening hole 16b for passing an RF rod 22 to be connected to the first RF electrode 14.

RF rods 22 for supplying power are respectively connected to the first RF electrode 14 and the second RF electrode 16, and the RF rods 22 extend through an inside of an internal space S of the ceramic shaft 20 and are connected to an external power supply (not illustrated) or grounded. Accordingly, the ceramic susceptor 10 can further include the RF rods 22 that are connected to the first RF electrode 14 and the second RF electrode 16 respectively and extend through the internal space S.

The first RF electrode 14 and/or the second RF electrode 16 may also have a function of an ESC electrode. The ESC electrode is an abbreviation of an electrostatic chuck (ESC) electrode, and is also referred to as an electrostatic electrode. When the first RF electrode 14 and/or the second RF electrode 16 function as the ESC electrodes, the first RF electrode 14 and/or the second RF electrode 16 chuck the wafer W placed on a top surface of the ceramic plate 12 by a Johnsen-Rahbek force, when a voltage is applied to them by the external power supply.

The lift pin hole 18 is provided to penetrate to the second surface 12b from the first surface 12a of the ceramic plate 12. As described above, the lift pin hole 18 is a hole that is used for inserting the lift pin (not illustrated) for lifting the wafer W after film deposition from below. That is to say, after film deposition, the lift pin comes out from the first surface 12a of the ceramic plate 12 through the lift pin hole 18, lifts the waver W upward, and can facilitate removal of the wafer W from the ceramic susceptor 10.

A shape in plan view of the lift pin hole 18 may be any shape such as a circle, and a polygon, but is preferably a circle. The number of lift pin holes 18 provided in the ceramic plate 12 is preferably three or four and is more preferably three. With the small number of holes like this, it is possible to sufficiently secure pivot points for lifting the wafer W by the lift pins (not illustrated) while securing the large effective area in the ceramic plate 12. A diameter of the lift pin hole 18 is not particularly limited, but is preferably from 1 to 5 mm, more preferably from 2 to 4 mm, and still more preferably from 2 to 3 mm.

The heater electrode 24 may be embedded in the position at a depth closer to the second surface 12b than the first RF electrode 14 and the second RF electrode 16 in the ceramic plate 12. The heater electrode 24 is not particularly limited, but for example, it can be an electrically conductive coil wired across the entire surface of the ceramic plate 12 in a single continuous line. A heater rod 26 is connected to both ends of the heater electrode 24 to supply power, the heater rod 26 extends through the inside of the internal space S and is connected to a heater power supply (not illustrated). When the heater electrode 24 is supplied with electric power from the heater power supply, it generates heat to heat the wafer W placed on the top surface of the ceramic plate 12. The heater electrode 24 is not limited to a coil, and may be, for example, a ribbon (a long, thin sheet), a mesh, or a print. Accordingly, the ceramic susceptor 10 further includes the heater rod 26 that is connected to the heater electrode 24 and extends through the internal space S.

The ceramic shaft 20 may be attached to the second surface 12b of the ceramic plate 12 (preferably coaxially). The ceramic shaft 20 is a cylindrical member including the internal space S, and can have a similar configuration to that of a ceramic shaft adopted in a known ceramic susceptor or ceramic heater. The internal space S is configured so that terminal rods such as the RF rod 22 and the heater rod 26 pass through the inside thereof. The ceramic shaft 20 is preferably made of a ceramic material similar to that of the ceramic plate 12. Accordingly, the ceramic shaft 20 preferably contains aluminum nitride or aluminum oxide, and more preferably contains aluminum nitride. An upper end surface of the ceramic shaft 20 is preferably bonded to the second surface 12b of the ceramic plate 12 by solid-state welding or diffusion bonding. An outside diameter of the ceramic shaft 20 is not particularly limited, but is preferably from 40 to 60 mm. An inside diameter of the ceramic shaft 20 (diameter of the internal space S) is not particularly limited, either, but is preferably from 33 to 55 mm.

An example of a method for using the ceramic susceptor 10 in a film deposition apparatus is as follows. The ceramic susceptor 10 is positioned in a chamber of the film deposition apparatus, and the wafer W is placed on the protrusions 12p of the ceramic plate 12. Then, RF current is passed through the first RF electrode 14 and the second RF electrode 16 to generate plasma between these electrodes and facing electrodes in the chamber. At this time, a voltage may be applied to the first RF electrode 14 and the second RF electrode 16 that also function as the ESC electrodes to thereby chuck the wafer W by a Johnsen-Rahbek force. Furthermore, a temperature of the ceramic plate 12 is obtained based on a detection signal of a thermocouple (not illustrated), and the voltage and the current that are applied to the heater electrode 24 are controlled so that the temperature reaches a target temperature. In such a state, film deposition can be performed on the upper surface of the wafer W by CVD or the like. After the film deposition, the lift pins (not illustrated) come out from the first surface 12a of the ceramic plate 12 through the lift pin holes 18, lift the wafer W upward, and assist in removal of the wafer W from the ceramic susceptor 10.

### EXAMPLES

The present invention will be described more specifically based on the following examples. However, the present invention is not limited to the following examples.

### Examples 1 to 7

### (1) Fabrication of Ceramic Susceptor

The ceramic susceptors 10 (ceramic heaters) having the structure as shown in FIGS. 1 and 2 were fabricated following a known procedure, by using components shown below.

### <Components and Specifications Thereof>

Ceramic plate 12: a disk-shaped aluminum nitride sintered body (diameter: 330 mm, thickness: 19 mm) (the first RF electrode 14, the second RF electrode 16, and the heater electrode 24 are embedded inside)
Ceramic shaft 20: a cylindrical aluminum nitride sintered body (height: 166 mm, outside diameter: 40 mm, inside diameter: 36 mm)
First RF electrode 14: circular metal mesh as shown in FIG. 3, that is embedded in the position at the depth of the distance L₁ shown in Table 1 from the top surface of the projection 12p in the ceramic plate 12 (made of molybdenum, diameter: 299 mm)
Opening hole 14a of the first RF electrode 14: three circular holes formed in rotationally symmetrical positions as shown in FIG. 3 (each of the opening holes 14a has an area that gives an S₁/S_{L} ratio shown in Table 1)
Second RF electrode 16: circular metal mesh as shown in FIG. 4, that is embedded in the position at the depth of the distance L₂ shown in Table 1 from the top surface of the projection 12p in the ceramic plate 12 (made of molybdenum, diameter: 315 mm)
Opening hole 16a of the second RF electrode 16: three circular holes formed in the rotationally symmetrical positions as shown in FIG. 4 (each of the opening holes 16a has the area that gives the S₂/S_{L} ratio shown in Table 1).
Opening hole 16b of the second RF electrode 16: one circular hole formed in the center position as shown in FIG. 4
Lift pin hole 18: three in the rotationally symmetrical positions as shown in FIG. 2 (shape: circle, diameter: 3.5 mm, sectional area S_{L} of the lift pin hole 18 when seen in plan view: 9.62 mm²)
RF rod 22: two terminal rods made of nickel
Heater electrode 24: two-zone heater including an inner zone heater circuit and an outer zone heater circuit, and each of the heater circuits is composed of a resistance heating body (material: molybdenum) in a three-dimensional coil shape that is placed in a single continuous line.
Heater rod 26: four terminal rods made of nickel (two terminal rods are connected to each of the inner zone heater circuit and the outer zone heater circuit).

The ceramic plate 12 in which the first RF electrode 14, the second RF electrode 16, and the heater electrode 24 described above were embedded was fabricated following the procedure below. First, aluminum nitride powder was press-molded to obtain a first aluminum nitride green compact. Aluminum nitride powder and the heater electrode 24 were positioned on the resultant first aluminum nitride green compact according to a predetermined circuit pattern and then press-molded to thereby obtain a second aluminum nitride green compact in which the heater electrode 24 was embedded. Aluminum nitride powder and the second RF electrode 16 were positioned on the resultant second aluminum nitride green compact and then press-molded to thereby obtain a third aluminum nitride green compact in which the second RF electrode 16 was further embedded. Aluminum nitride powder and the first RF electrode 14 were positioned on the resultant third aluminum nitride green compact and press-molded to thereby obtain a fourth aluminum nitride green compact in which the first RF electrode 14 was further embedded. In this manner, the press-molded body was obtained, which was made of an aluminum nitride green compact in which the first RF electrode 14, the second RF electrode 16, and the heater electrode 24 were embedded as shown in FIG. 1. The resultant press-molded body (laminated body) was fired under known conditions in a nitrogen atmosphere to thereby obtain the ceramic plate 12 in which the first RF electrode 14, the second RF electrode 16, and the heater electrode 24 were embedded.

### (2) Evaluation

The following evaluations were performed on the resultant ceramic susceptor (ceramic heater).

### <Film Deposition Evaluation>

The ceramic susceptor 10 was installed in the chamber of the plasma CVD apparatus. Then, in the plasma CVD apparatus in which the ceramic susceptor 10 was mounted, plasma was generated under the conditions of the film deposition temperature: 600° C., the internal furnace pressure: 3 Torr, and the RF electric power: 500 W. At this time, TEOS (Tetraethyl orthosilicate) as a precursor (precursory substance), Ar (flow rate: 100 sccm) as carrier gas, and O₂ (flow rate: 100 sccm) as reaction gas were introduced into the chamber to deposit an SiO₂ film having a thickness of 300 mm on an Si wafer.

For the resultant SiO₂ film, the maximum value Tₘₐₓ and the minimum value Tₘᵢₙ of the film thickness were measured, and the variation T_{d}(%) of the film thickness was calculated based on the formula below:

T_{d}=[(Tₘₐₓ−Tₘᵢₙ)/(Tₘₐₓ)]×100

The obtained variation in film thickness was applied to the following evaluation criteria:
Evaluation A: film thickness variation is less than 5%
Evaluation B: film thickness variation is from 5% or more to 8% or less
Evaluation C: film thickness variation is larger than 8% to thereby grade and evaluate the uniformity of the film thickness. The obtained evaluation result is as shown in Table 1.

TABLE 1

| | | | Depth position L₁ | Depth position L₂ | Film |
|---|---|---|---|---|---|
| | Area ratio | Area ratio | of first RF | of second RF | deposition |
| | S₁/S_{L} | S₂/S_{L} | electrode (mm) | electrode (mm) | evaluation |
| Example 1 | 4.0 | 2.0 | 1.0 | 2.0 | A |
| Example 2 | 6.0 | 3.0 | 1.2 | 2.5 | A |
| Example 3 | 8.0 | 4.0 | 1.3 | 3.0 | A |
| Example 4 | 10.0 | 4.5 | 1.5 | 2.8 | A |
| Example 5 | 4.0 | 2.0 | 0.8 | 1.8 | B |
| Example 6* | 2.0 | 1.5 | 0.9 | 3.5 | C |
| Example 7* | 11.0 | 5.0 | 1.8 | 2.8 | C |

*Comparative example

What is claimed is:

1. A ceramic susceptor, comprising:
a ceramic plate in a disk shape having a first surface provided with a plurality of projections having a constant height, and a second surface opposing the first surface;
a first RF electrode that is made of metal mesh having a circular shape with a diameter d₁, and is embedded in a position at a depth of a distance L₁ from top surfaces of the projections in the ceramic plate;
a second RF electrode that is made of metal mesh having a circular shape with a diameter d₂, and is embedded in a position at a depth of a distance L₂ (where L₂>L₁) from the top surfaces of the projections in the ceramic plate; and
a plurality of lift pin holes each having a sectional area S_{L} that penetrate to the second surface from the first surface of the ceramic plate,
wherein the first RF electrode has opening holes each having an area S₁ in a plurality of positions corresponding to the lift pin holes, and the second RF electrode has opening holes each having an area S₂ in a plurality of positions corresponding to the lift pin holes,
wherein the sectional area S_{L}, the area S₁, and the area S₂ satisfy relationships below:
3.0≤S₁/S_{L}≤10.5, and
2.0≤S₂/S_{L}≤4.5.

2. The ceramic susceptor according to claim 1, wherein when expressed in units of millimeters, the distance L₁ and the distance L₂ satisfy relationships below:
0.9≤L₁≤1.5, and
2.0≤L₂≤3.0.

3. The ceramic susceptor according to claim 1, wherein when expressed in units of millimeters, the diameter d₁ and the diameter d₂ satisfy relationships below:
290≤d₁≤300, and
310≤d₂≤350.

4. The ceramic susceptor according to claim 1, wherein the ceramic plate has a diameter of from 330 to 380 mm.

5. The ceramic susceptor according to claim 1, wherein the ceramic plate contains aluminum nitride and/or aluminum oxide.

6. The ceramic susceptor according to claim 1, further comprising a ceramic shaft in a cylindrical shape that is attached to the second surface of the ceramic plate, and includes an internal space.

7. The ceramic susceptor according to claim 6, further comprising RF rods that are connected to the first RF electrode and the second RF electrode respectively, and extend through the internal space.

8. The ceramic susceptor according to claim 1, wherein the lift pin holes have a circular shape in plan view.

9. The ceramic susceptor according to claim 1, wherein the number of the lift pin holes is three or four.

10. The ceramic susceptor according to claim 1, wherein each of the lift pin holes has a diameter of 1 to 5 mm.

11. The ceramic susceptor according to claim 1, wherein the first RF electrode and/or the second RF electrode also has a function of an ESC electrode.

12. The ceramic susceptor according to claim 1, further comprising a heater electrode that is embedded in a position at a depth closer to the second surface than the first RF electrode and the second RF electrode in the ceramic plate.

13. The ceramic susceptor according to claim 12, further comprising:
a ceramic shaft in a cylindrical shape that is attached to the second surface of the ceramic plate, and includes an internal space; and
a heater rod that is connected to the heater electrode, and extends through the internal space.
